(19) United States
(12) Patent Application Publication
(10) Pub. No.: US 2026/0049172 A1
(43) Pub. Date: Feb. 19, 2026

(54) EPOXY RESIN COMPOSITION FOR ENCAPSULATING SEMICONDUCTOR DEVICE AND SEMICONDUCTOR DEVICE ENCAPSULATED USING THE SAME

(71) Applicant: SAMSUNG SDI CO., LTD., Yongin-si (KR)

(72) Inventors: Dong Hwan LEE, Suwon-si (KR); Ki Hyeok KWON, Suwon-si (KR); Jun Woo LEE, Suwon-si (KR); Min Soo KIM, Suwon-si (KR); Young Joon LEE, Suwon-si (KR); Tae Shin EOM, Suwon-si (KR); Yong Han CHO, Suwon-si (KR)

(21) Appl. No.: 19/077,349

(22) Filed: Mar. 12, 2025

(30) Foreign Application Priority Data
Mar. 13, 2024 (KR) 10-2024-0035273

(51) Int. Cl. C08G 59/24; C08K 7/18; H01L 23/29

(52) U.S. Cl. CPC C08G 59/245; C08K 7/18; H01L 23/295

(57) ABSTRACT

An epoxy resin composition for encapsulation of semiconductor devices and a semiconductor device encapsulated using the epoxy resin composition, the epoxy resin composition including an epoxy resin, a curing agent, inorganic filler, and a curing catalyst, wherein the epoxy resin includes at least one epoxy resin compound represented by Formula 1:

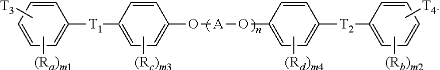

### CROSS-REFERENCE TO RELATED APPLICATION

The present application claims priority and the benefit of Korean Patent Application No. 10-2024-0035273, filed on Mar. 13, 2024 in the Korean Intellectual Property Office, the entire disclosure of which is incorporated herein by reference.

### 1. FIELD

Embodiments relate to an epoxy resin composition for encapsulation of semiconductor devices and a semiconductor device encapsulated using the same.

### 2. DESCRIPTION OF THE RELATED ART

Recently, the degree of integration of semiconductor devices has been improved. In a semiconductor apparatus in which a stack of high-density semiconductor devices may be encapsulated in a small and thin package, failure such as cracking or malfunction of the package may occur frequently due to heat generation during operation of the semiconductor device.

### SUMMARY

Embodiments are directed to an epoxy resin composition for encapsulation of semiconductor devices, the epoxy resin composition including an epoxy resin, a curing agent, an inorganic filler, and a curing catalyst, wherein the epoxy resin includes at least one epoxy resin compound represented by Formula 1:

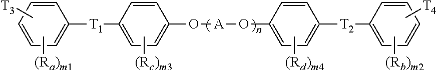

wherein A is a substituted or unsubstituted ethylene group or a substituted or unsubstituted propylene group, n is an integer of 1 to 10, T₁ and T₂ are each independently a single bond, O, or S, T₃ and T₄ are each independently a compound represented by Formula 2:

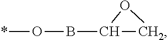

* is a linking site to a carbon of Formula 1, B is a substituted or unsubstituted C₁ to C₅ alkylene group, Rₐ, R_{b}, R_{c}, and R_{d} are each independently a substituted or unsubstituted C₁ to C₁₀ alkyl group, a substituted or unsubstituted C₃ to C₁₀ cycloalkyl group, a substituted or unsubstituted C₆ to C₁₀ aryl group, or a substituted or unsubstituted C₇ to C₁₀ arylalkyl group, m1 and m2 are each independently an integer of 0 to 4, and m3 and m4 are each independently an integer of 0 to 4

The at least one epoxy resin compound represented by Formula 1 may include at least one compound represented by Formula 3 or Formula 4,

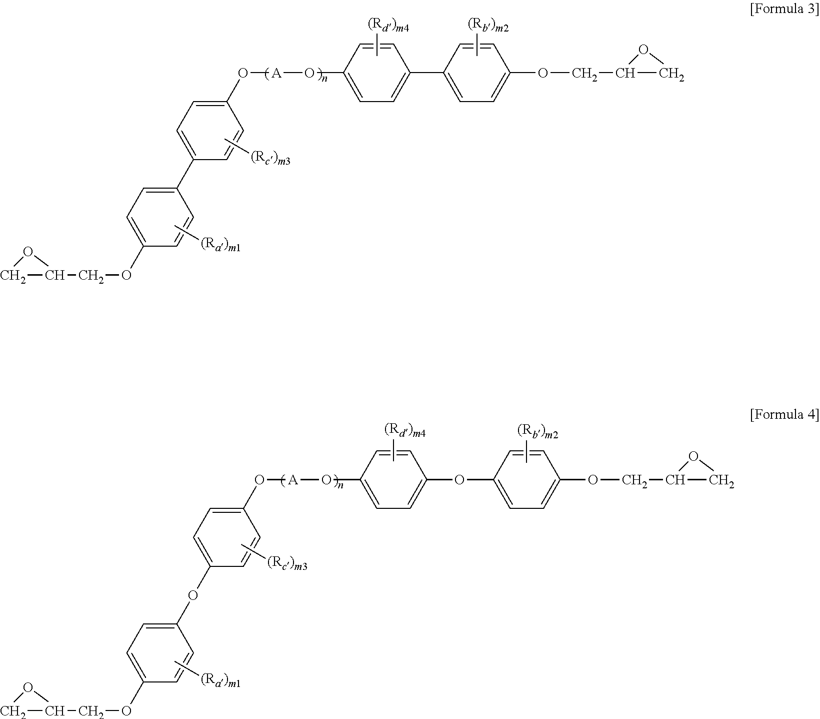

wherein Rₐ′, R_{b}′, R_{c}′, and R_{d}′ may each independently be a substituted or unsubstituted C₁ to C₁₀ alkyl group, and A, m1, m2, m3, m4, and n may be defined the same as those of Formula 1.

The at least one epoxy resin compound represented by Formula 1 may include at least one compound represented by Formula 5 to Formula 8,

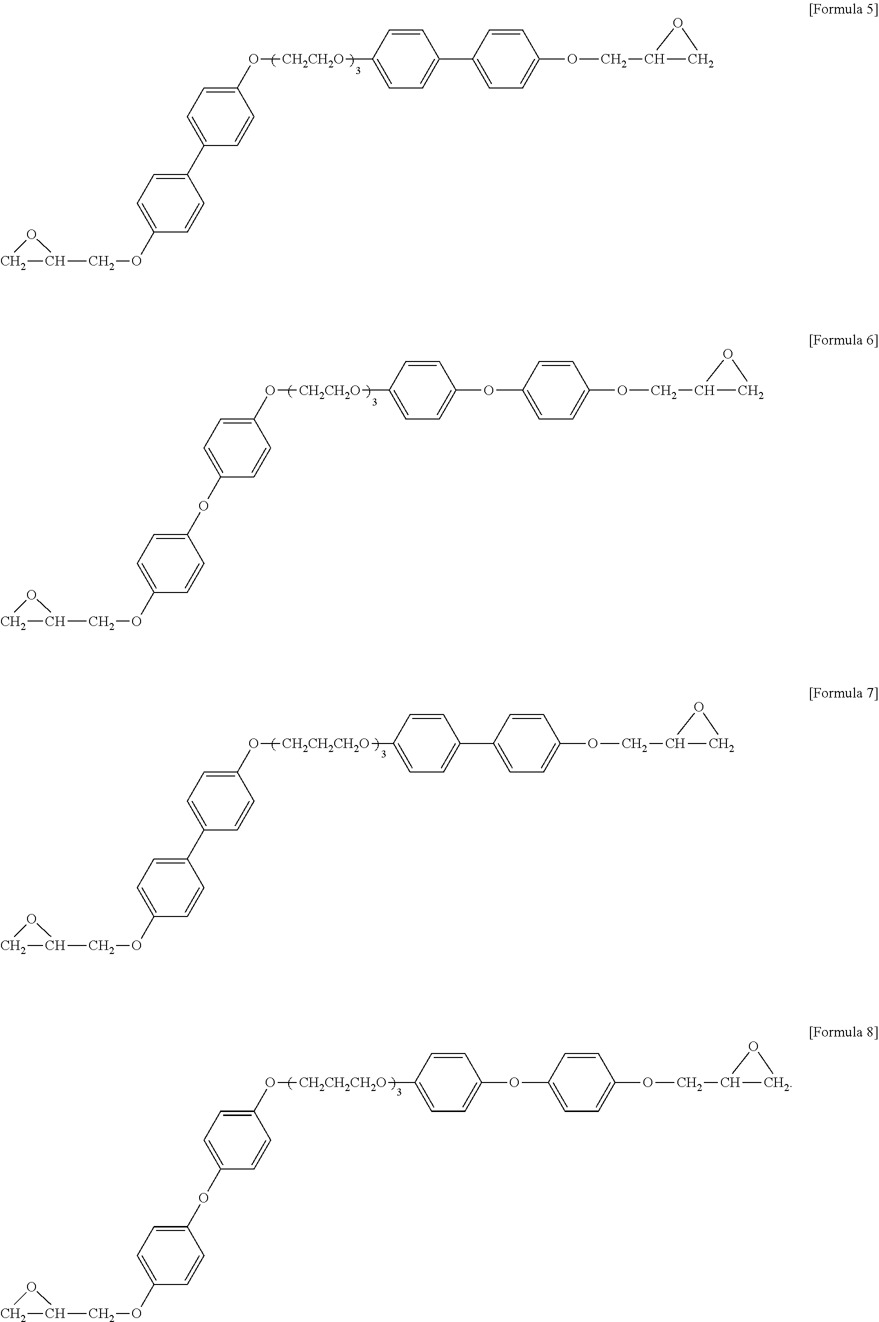

The at least one epoxy resin compound represented by Formula 1 may be included in the epoxy resin composition in an amount of 0.1 wt % to 17 wt %, based on a total weight of the epoxy resin composition.

The inorganic filler may include alumina.

The epoxy resin composition may include, based on a total weight of the epoxy resin composition, 2 wt % to 17 wt % of the epoxy resin, 0.5 wt % to 13 wt % of the curing agent, 50 wt % to 95 wt % of the inorganic filler, and 0.01 wt % to 5 wt % of the curing catalyst.

The embodiments may be realized by providing a semiconductor device encapsulated using the epoxy resin composition according to some embodiments.

### DETAILED DESCRIPTION OF THE INVENTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not an exclusive term, e.g., “A or B” would include A, B, or A and B.

As used herein to represent a specific numerical range, “X to Y” means “greater than or equal to X and less than or equal to Y”.

As used herein, the term “substituted” in the expression “substituted or unsubstituted” means that at least one hydrogen atom of a corresponding functional group is substituted with a hydroxyl group, an amino group, a nitro group, a cyano group, a C₁ to C₂₀ alkyl group, a C₁ to C₂₀ haloalkyl group, a C₆ to C₃₀ aryl group, a C₃ to C₃₀ heteroaryl group, a C₃ to C₁₀ cycloalkyl group, a C₃ to C₁₀ heterocycloalkyl group, a C₇ to C₃₀ arylalkyl group, or a C₁ to C₃₀ heteroalkyl group.

To impart high thermal conductivity to an epoxy resin composition for encapsulation of semiconductor devices, relatively large amounts of inorganic filler may be required. However, the use of large amounts of inorganic filler may cause an increase in viscosity of the composition and reduction in fluidity of the composition, which may result in difficulty forming a semiconductor package. To solve such problems, use of alumina, which may be an inorganic filler having relatively high thermal conductivity, may be considered. However, since an epoxy resin included in the composition may have a very low thermal conductivity of about 0.2 W/m·K, there may be difficulty increasing thermal conductivity of the composition even with the use of alumina.

In accordance with one aspect of the present disclosure, an epoxy resin composition for encapsulation of semiconductor devices may include, e.g., an epoxy resin, a curing agent, an inorganic filler, or a curing catalyst, wherein the epoxy resin may include at least one epoxy resin compound represented by Formula 1. The epoxy resin including the at least one epoxy resin compound represented by Formula 1 may help improve the heat dissipation capacity of the composition due to high thermal conductivity thereof. The epoxy resin including the at least one epoxy resin compound represented by Formula 1 may help improve fluidity of the composition due to low viscosity thereof. The epoxy resin including the at least one epoxy resin compound represented by Formula 1 may help improve crack resistance and reliability of the composition through an increase in toughness of the composition. The epoxy resin including the at least one epoxy resin compound represented by Formula 1 may help suppress heat-induced malfunction or failure of a semiconductor package and may help improve reliability of the semiconductor package by maintaining the surface temperature of a semiconductor at low levels. In an implementation, the epoxy resin including the at least one epoxy resin compound represented by Formula 1 may help reduce moisture absorption of the composition while reducing solder joint stress.

### Epoxy Resin

The epoxy resin may include at least one epoxy resin compound represented by Formula 1.

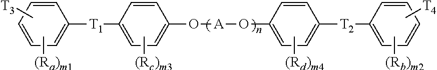

In Formula 1, A may be or include, e.g., a substituted or unsubstituted ethylene group or a substituted or unsubstituted propylene group.

n may be, e.g., an integer of 1 to 10.

T₁ and T₂ may each independently be, e.g., a single bond, O, or S.

T₃ and T₄ may each independently be, e.g., a compound represented by Formula 2.

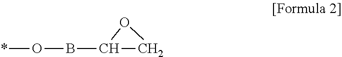

* is a linking site to a carbon of Formula 1.

B may be, e.g., a substituted or unsubstituted C₁ to C₅ alkylene group.

Rₐ, R_{b}, R_{c}, and R_{d} may each independently be, e.g., a substituted or unsubstituted C₁ to C₁₀ alkyl group, a substituted or unsubstituted C₃ to C₁₀ cycloalkyl group, a substituted or unsubstituted C₆ to C₁₀ aryl group, or a substituted or unsubstituted C₇ to C₁₀ arylalkyl group.

m1 and m2 may each independently be, e.g., an integer of 0 to 4.

m3 and m4 may each independently be, e.g., an integer of 0 to 4.

The epoxy resin including the at least one epoxy resin compound represented by Formula 1 may include, e.g., a liquid crystalline epoxy resin including a repeat unit including, e.g., an ethylene oxide group or a propylene oxide group; or a biphenyl group, a biphenyl ether group, or a biphenyl thioether group. Thus, the epoxy resin including the at least one epoxy resin compound represented by Formula 1 may help significantly improve heat dissipation capacity of the composition due to high thermal conductivity thereof. In an implementation, the epoxy resin including the epoxy resin compound represented by Formula 1 may help provide high toughness to the composition, thereby helping suppress breakage and cracking of a semiconductor device if the semiconductor device is subjected to external shock or reliability testing. In an implementation, the epoxy resin including the at least one epoxy resin compound represented by Formula 1 may help improve fluidity and processability of the composition due to low viscosity thereof.

In Formula 1, “single bond” may refer to a direct chemical bond between two aromatic groups.

In one embodiment, in Formula 1, T₁ and T₂ may each independently be, e.g., a single bond or O. In an implementation, T₁ and T₂ may each independently be, e.g., a single bond.

In one embodiment, in Formula 1, n may be, e.g., an integer of 3 to 8. In an implementation, n may be, e.g., an integer of 3 to 5.

In one embodiment, in Formula 1, A may be, e.g., an ethylene group, an n-propylene group, or an iso-propylene group.

In one embodiment, in Formula 1, Rₐ, R_{b}, R_{c}, and R_{d} may each independently be, e.g., a substituted or unsubstituted C₁ to C₁₀ alkyl group or a substituted or unsubstituted C₆ to C₁₀ aryl group. In an implementation, Rₐ, R_{b}, R_{c}, and R_{d} may each independently be, e.g., a substituted or unsubstituted C₁ to C₁₀ alkyl group.

In one embodiment, in Formula 1, m1, m2, m3, and m4 may each independently be, e.g., an integer of 0 to 4. In an implementation, m1, m2, m3, and m4 may each independently be, e.g., an integer of 0 or 1.

The epoxy resin composition may include, e.g., one or more types of epoxy resin compounds represented by Formula 1.

The at least one epoxy resin compound represented by Formula 1 may include, e.g., at least one compound represented by Formula 3 or Formula 4.

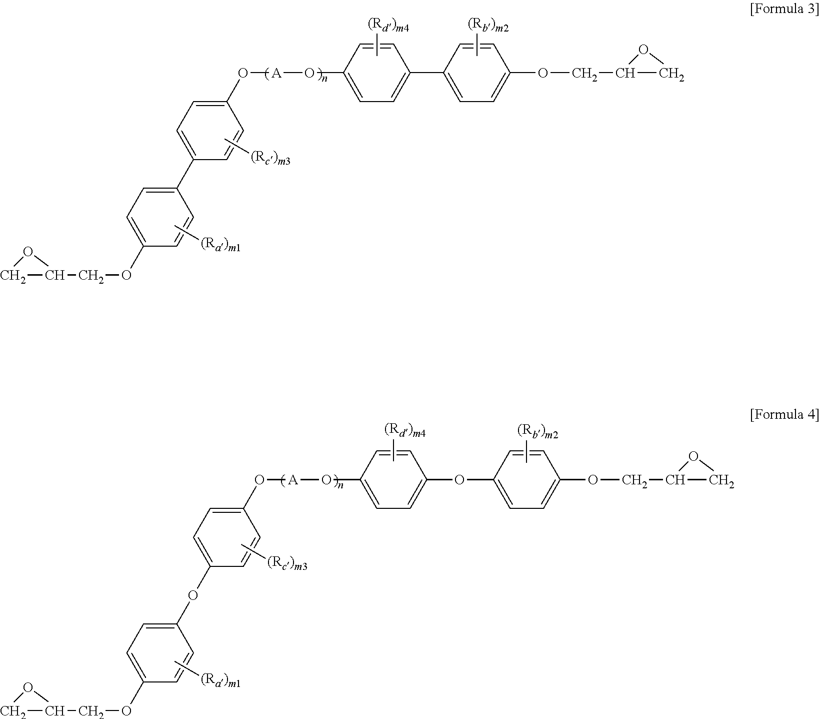

In Formula 3 and Formula 4, Rₐ′, R_{b}′, R_{c}′, and R_{d}′ may each independently be or include, e.g., a substituted or unsubstituted C₁ to C₁₀ alkyl group. A, n, m1, m2, m3, and m4 may be defined the same as those of Formula 1.

The at least one epoxy resin compound represented by Formula 1 may include, e.g., at least one compound represented by Formula 5 to Formula 8.

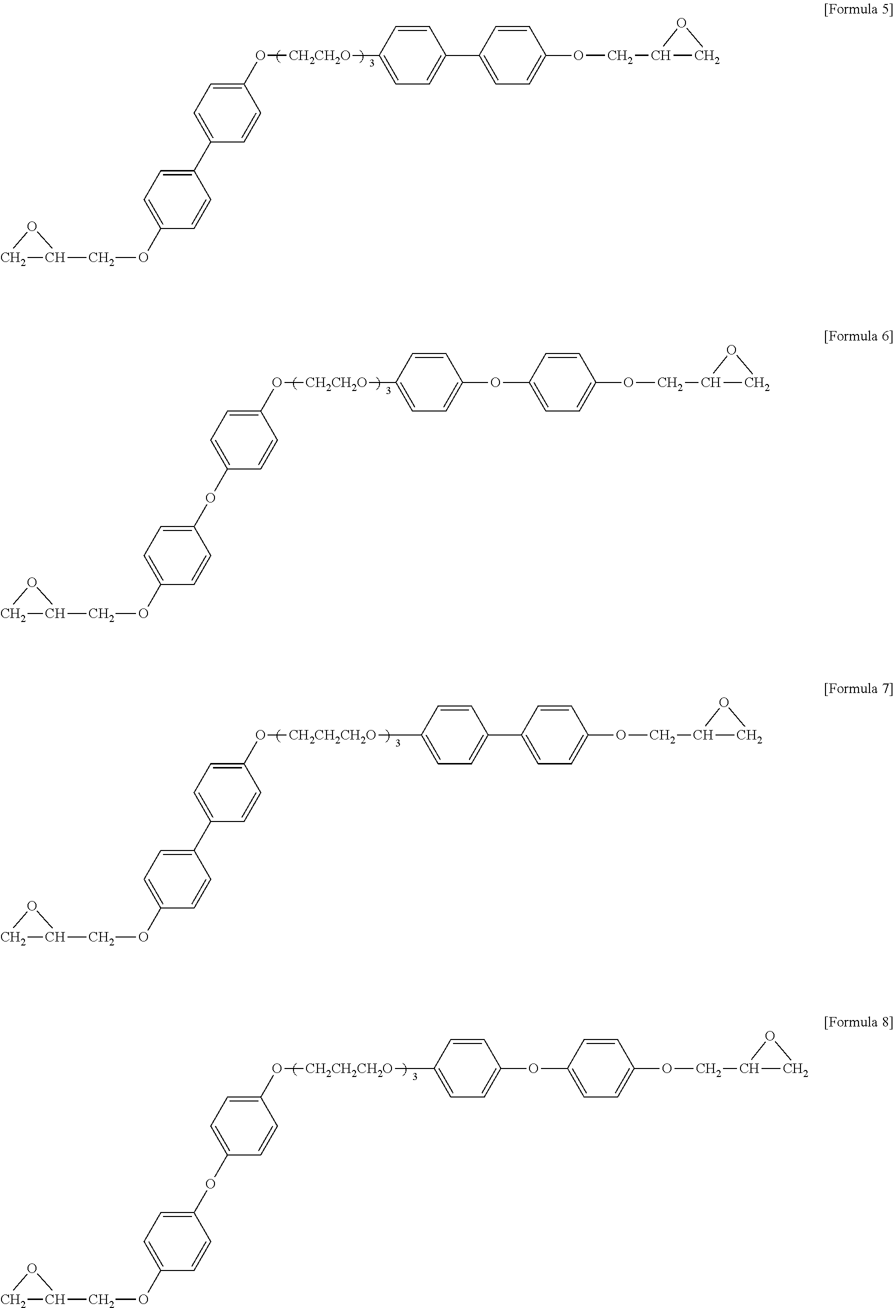

As the at least one epoxy resin compound represented by Formula 1, these compounds may be used alone or in combination thereof in the epoxy resin composition. The at least one epoxy resin compound represented by Formula 1 may be included in the epoxy resin composition in an amount of 0.1 wt % to 17 wt %, e.g., 2 wt % to 17 wt % or 2 wt % to 10 wt %, based on a total weight of the epoxy resin composition. Maintaining the amount of the at least one epoxy resin compound represented by Formula 1 in this range may help ensure that the at least one epoxy resin compound represented by Formula 1 may help improve heat dissipation capacity of the composition without sacrificing curability of the composition.

The epoxy resin may be prepared, e.g., by a suitable epoxy resin preparation method with reference to Formula 1.

The epoxy resin of the epoxy resin composition may, e.g., consist solely of the at least one epoxy resin compound represented by Formula 1. In an implementation, the at least one epoxy resin compound represented by Formula 1 may be included in the epoxy resin composition, in an amount of 100 wt %, based on a total weight of the epoxy resin contained in the epoxy resin composition.

In an implementation, the epoxy resin composition may further include, e.g., an epoxy resin other than the at least one epoxy resin compound represented by Formula 1 without affecting the desired effects of the present invention. For descriptive convenience, the at least one epoxy resin compound represented by Formula 1 will be referred to as a first epoxy resin, and the epoxy resin other than the at least one epoxy resin compound represented by Formula 1 will be referred to as a second epoxy resin.

The second epoxy resin may be an epoxy resin containing at least two epoxy groups in a molecular structure thereof and may include, e.g., bisphenol A epoxy resins, bisphenol F epoxy resins, phenol novolac epoxy resins, tert-butyl catechol epoxy resins, naphthalene epoxy resins, glycidyl amine epoxy resins, cresol novolac epoxy resins, biphenyl epoxy resins, phenol aralkyl epoxy resins, linear aliphatic epoxy resins, cycloaliphatic epoxy resins, heterocyclic epoxy resins, spirocyclic epoxy resins, cyclohexanedimethanol epoxy resins, trimethylol epoxy resins, halogenated epoxy resins, or the like. As the second epoxy resin, these epoxy resins may be used alone or as a mixture thereof.

The epoxy resin may be present in the epoxy resin composition in an amount of 2 wt % to 17 wt %, e.g., 2 wt % to 10 wt %, based on the total weight of the epoxy resin composition. Maintaining the amount of epoxy resin within these ranges may help ensure that the composition can avoid reduction in curability.

### Curing Agent

The curing agent may include, e.g., polyfunctional phenol resins including aralkyl-type phenol resins, novolac-type phenol resins, Xylok-type phenol resins, cresol novolac-type phenol resins, naphthol-type phenol resins, terpene-type phenol resins, dicyclopentadiene phenol resins, novolac-type phenol resins synthesized from bisphenol A or resol, or the like, polyhydric phenol compounds including, e.g., tris(hydroxyphenyl)methane, dihydroxybiphenyl, or the like, acid anhydrides including, e.g., maleic anhydride, phthalic anhydride, or the like, and aromatic amines including, e.g., metaphenylenediamine, diaminodiphenylmethane, diaminodiphenylsulfone, or the like. In an implementation, the curing agent may include, e.g., a Xylok-type phenol resin or an aralkyl-type phenol resin.

The curing agent may be included in the epoxy resin composition in an amount of 0.5 wt % to 13 wt %, based on a total weight of epoxy resin composition. Maintaining the amount of curing agent within this range may help ensure that the composition may avoid reduction in curability.

### Inorganic Filler

The inorganic filler may serve to help improve mechanical properties of the epoxy resin composition while helping reduce internal stress of the epoxy resin composition. In an implementation, the inorganic filler may help increase thermal conductivity and heat dissipation capacity of the epoxy resin composition, may help improve fluidity of the epoxy resin composition, and may help reduce thermal expansion and moisture absorption of the epoxy resin composition.

The inorganic filler may include, e.g., fused silica, crystalline silica, calcium carbonate, magnesium carbonate, alumina, magnesia, clay, talc, calcium silicate, titanium oxide, antimony oxide, or glass fiber.

In an implementation, the inorganic filler may include, e.g., alumina. The alumina may have a thermal conductivity of 25 W/m·K to 30 W/m·K and may be effective at increasing thermal conductivity of the composition.

In an implementation, the alumina may have, e.g., a spherical or aspherical shape. If the alumina has a spherical shape, the composition may have improved fluidity. The alumina may have an average particle diameter (D₅₀) of 0.5 μm to 50 μm, e.g., 0.5 μm to 30 μm. Maintaining the average particle diameter (D₅₀) of the alumina within these ranges may help ensure that the composition may have good properties in terms of fluidity and thermal conductivity. In one embodiment, the alumina may include a mixture of two types of alumina having different average particle diameters (D₅₀). In an implementation, the alumina may be a mixture in which a first type of alumina and a second type of alumina are present in a weight ratio of 1:1 to 10:1, wherein the first type of alumina may have a greater average particle diameter (D₅₀) than the second type of alumina. The alumina may be coated with the epoxy resin or the curing agent prior to being incorporated into the composition, as needed.

The content of the inorganic filler in the composition may be varied depending on properties required for the composition, such as thermal conductivity, moldability, low stress, and strength at high temperatures. In some embodiments, the inorganic filler may be included in the epoxy resin composition in an amount of 50 wt % to 95 wt %, e.g., 70 wt % to 95 wt %, 85 wt % to 95 wt %, based on a total weight of the epoxy resin composition. Maintaining the amount of inorganic filler within these ranges may help ensure that the epoxy resin composition may have good properties in terms of flame retardancy, fluidity, and reliability.

### Curing Catalyst

The curing catalyst may include, e.g., a tertiary amine compound, an organometallic compound, an organophosphorus compound, an imidazole compound, or a boron compound. The tertiary amine compound may include, e.g., benzyldimethylamine, triethanolamine, triethylenediamine, diethylaminoethanol, tri(dimethylaminomethyl)phenol, 2,2-(dimethylaminomethyl)phenol, 2,4,6-tris(diaminomethyl)phenol, tri-2-ethyl hexanoate, or the like. The organometallic compound may include, e.g., chromium acetylacetonate, zinc acetylacetonate, nickel acetylacetonate, or the like. The organophosphorus compound may include, e.g., triphenylphosphine, tris-4-methoxyphosphine, triphenylphosphine-triphenylborane, a triphenylphosphine-1,4-benzoquinone adduct, or the like. The imidazole compound may include, e.g., 2-methylimidazole, 2-phenylimidazole, 2-aminoimidazole, 2-methyl-1-vinylimidazole, 2-ethyl-4-methylimidazole, 2-heptadecyl imidazole, or the like. The boron compound may include, e.g., triphenylphosphine tetraphenyl borate, a tetraphenylboron salt, trifluoroborane-n-hexylamine, trifluoroborane monoethylamine, tetrafluoroborane triethylamine, tetrafluoroborane amine, or the like. In an implementation, 1,5-diazabicyclo[4.3.0]non-5-ene (DBN), 1,8-diazabicyclo[5.4.0]undec-7-ene (DBU), or a phenol novolac resin salt may be used as the curing catalyst.

The curing catalyst may be included, e.g., in the form of an adduct prepared by pre-reacting the curing catalyst with the epoxy resin or the curing agent.

The curing catalyst may be included in the epoxy resin composition, e.g., in an amount of 0.01 wt % to 5 wt %, based on a total weight of the epoxy resin composition. Maintaining the amount of the curing catalyst in this range may help ensure that the curing catalyst may help promote curing of the composition without sacrificing fluidity of the composition.

The epoxy resin composition may further include suitable additives used in epoxy resin compositions for encapsulation of semiconductor devices. In some embodiments, the additives may include, e.g., a coupling agent, a release agent, a colorant, a stress relieving agent, a crosslinking enhancer, or a leveling agent.

The coupling agent may serve to increase interfacial strength between the epoxy resin and the inorganic filler through reaction with the epoxy resin and the inorganic filler and may include, e.g., a silane coupling agent. The silane coupling agent may include any silane coupling agent that may increase interfacial strength between the epoxy resin and the inorganic filler through reaction with the epoxy resin and the inorganic filler. The silane coupling agent may include, e.g., epoxy silane, aminosilane, ureido silane, mercapto silane, an alkyl silane, or the like. These coupling agents may be used alone or in combination thereof. The coupling agent may be present in the epoxy resin composition in an amount of 0.01 wt % to 5 wt %, e.g., 0.05 wt % to 3 wt %, based on a total weight of the epoxy resin composition. Maintaining the amount of coupling agent within these ranges may help ensure that a cured product of the epoxy resin composition may have enhanced strength.

The release agent may include, e.g., paraffin wax, ester wax, higher fatty acids, metallic salts of higher fatty acids, natural fatty acids, and metallic salts of natural fatty acids. The release agent may be present in the epoxy resin composition an amount of 0.1 wt % to 1 wt %, based on a total weight of the epoxy resin composition.

The colorant may include, e.g., carbon black. The colorant may be present in the epoxy resin composition in an amount of 0.1 wt % to 1 wt %, based on a total weight of the epoxy resin composition.

The stress relieving agent may include, e.g., modified silicone oils, silicone elastomers, silicone powders, and silicone resins. The stress relieving agent may be present in the epoxy resin composition in an amount of 2 wt % or less, e.g., 1 wt % or less or 0.1 wt % to 1 wt %, based on a total weight of the epoxy resin composition.

The additives may be present in the epoxy resin composition in an amount of 0.1 wt % to 5 wt %, e.g., 0.1 wt % to 3 wt %, based on a total weight of the epoxy resin composition.

The epoxy resin composition may be prepared, e.g., by uniformly mixing the aforementioned components in a Henschel mixer or a Lödige mixer, melt-kneading the mixture in a roll mill or a kneader at, e.g., 90° C. to 120° C., and subjecting the resulting product to cooling and pulverization.

In accordance with another aspect of the present disclosure, a semiconductor device may be encapsulated using the epoxy resin composition for encapsulation of semiconductor devices according to an embodiment. The semiconductor device may be encapsulated with the epoxy resin composition by any suitable method, such as transfer molding, injection molding, casting, or compression molding. In one embodiment, the semiconductor device may be encapsulated with the epoxy resin composition by low-pressure transfer molding. In another embodiment, the semiconductor device may be encapsulated with the epoxy resin composition by compression molding.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparative Example 1: Preparation of Epoxy Resin

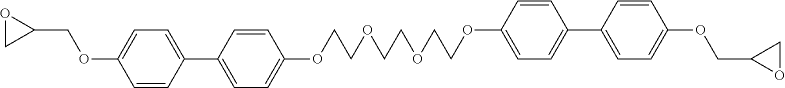 [SMILES: c1cc(-c2ccc(OCC3CO3)cc2)ccc1OCCOCCOCCOc1ccc(-c2ccc(OCC3CO3)cc2)cc1]

In a 500 mL reactor placed in a microwave reactor (CEM Discovery, CEM Co., Ltd.), 100 mL of dimethylformamide (DMF) as a solvent, 4,4′-dihydroxybiphenyl ether (37.2 g), and triethylene glycol (15 g) were introduced together with 20 mL of trimethylamine, followed by reaction at a temperature of 150° C. and a power of 150 W for 1 hour. Thereafter, the solvent was dried under reduced pressure, followed by purification of the reaction product through a silica gel column using a mixture of ethyl acetate and hexane (1:6) as a solvent. Thereafter, 38 g of a solid powder (yield: 78%) obtained through purification through the silica gel column was placed in a 500 mL reactor together with benzyltrimethylammonium bromide (5.0 g) and an excess of epichlorohydrin (300 mL), followed by reaction at 110° C. for 1 hour. Thereafter, NaOH (6 g) was added to the reactor, followed by reaction for 2 hours. Thereafter, the solvent was removed under reduced pressure, followed by purification of the reaction product with DI water, thereby obtaining 37 g of a semi-solid compound at a yield of 62%. NMR, LC-MS and elemental analysis confirmed that the corresponding compound was a compound represented by Formula 5 (A1).

¹H NMR (400 MHz, DMSO-d6): 7.52-7.46 (m, 4H), 7.43-7.37 (m, 4H), 7.03-6.93 (m, 4H), 6.89-6.78 (m, 4H), 4.20 (m, 2H) 4.14-4.01 (m, 4H), 3.90 (m, 2H) 3.81-3.73 (m, 4H), 3.48-3.44 (m, 4H) 3.33 (m, 2H), 2.75 (m, 2H), 2.61 (m, 2H) ppm; LC-MS m/z=598 (M⁺); Anal. Calcd for C₃₆H₃₈O₈: C, 72.22; H, 6.40; Found: C, 72.38; H, 6.46.

### Preparative Example 2: Preparation of Epoxy Resin

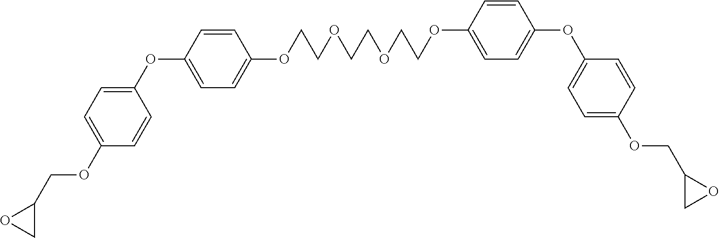 [SMILES: c1cc(Oc2ccc(OCC3CO3)cc2)ccc1OCCOCCOCCOc1ccc(Oc2ccc(OCC3CO3)cc2)cc1]

In a 500 mL reactor placed in a microwave reactor (CEM Discovery, CEM Co., Ltd.), 100 mL of dimethylformamide (DMF) as a solvent, 4,4′-dihydroxybiphenyl ether (40.4 g), and triethylene glycol (15 g) were introduced together with 20 mL of trimethylamine, followed by reaction at a temperature of 150° C. and a power of 150 W for 1 hour. Thereafter, the solvent was dried under reduced pressure, followed by purification of the reaction product through a silica gel column using a mixture of ethyl acetate and hexane (1:6) as a solvent. Thereafter, 42 g of a solid powder (yield: 82%) obtained through purification through the silica gel column was placed in a 500 mL reactor together with benzyltrimethylammonium bromide (5.0 g) and an excess of epichlorohydrin (300 mL), followed by reaction at 110° C. for 1 hour. Thereafter, NaOH (6 g) was added to the reactor, followed by reaction for 2 hours. Thereafter, the solvent was removed under reduced pressure, followed by purification of the reaction product with DI water, thereby obtaining 44 g of a semi-solid compound at a yield of 70%. NMR, LC-MS and elemental analysis confirmed that the corresponding compound was a compound represented by Formula 6 (A2).

¹H NMR (400 MHz, DMSO-d6): 6.94-6.68 (m, 16H), 4.21 (m, 2H) 4.15-4.01 (m, 4H), 3.92 (m, 2H) 3.80-3.72 (m, 4H), 3.48-3.44 (m, 4H) 3.30 (m, 2H), 2.75 (m, 2H), 2.59 (m, 2H) ppm; LC-MS m/z=630 (M⁺); Anal. Calcd for C₃₆H₃₈O₁₀: C, 68.56; H, 6.07; Found: C, 68.78; H, 6.28.

### Preparative Example 3: Preparation of Epoxy Resin

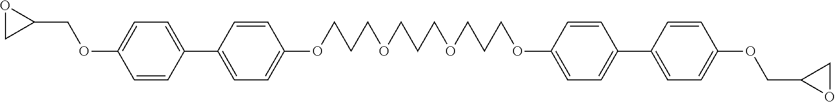 [SMILES: c1cc(-c2ccc(OCC3CO3)cc2)ccc1OCCCOCCCOCCCOc1ccc(-c2ccc(OCC3CO3)cc2)cc1]

In a 500 mL reactor placed in a microwave reactor (CEM Discovery, CEM Co., Ltd.), 100 mL of dimethylformamide (DMF) as a solvent, 4,4′-dihydroxybiphenyl ether (37.2 g), and triethylene glycol (19 g) were introduced together with 20 mL of trimethylamine, followed by reaction at a temperature of 150° C. and a power of 150 W for 1 hour. Thereafter, the solvent was dried under reduced pressure, followed by purification of the reaction product through a silica gel column using a mixture of ethyl acetate and hexane (1:6) as a solvent. Thereafter, 30 g of a solid powder (yield: 57%) obtained through purification through the silica gel column was placed in a 500 mL reactor together with benzyltrimethylammonium bromide (5.0 g) and an excess of epichlorohydrin (300 mL), followed by reaction at 110° C. for 1 hour. Thereafter, NaOH (6 g) was added to the reactor, followed by reaction for 2 hours. Thereafter, the solvent was removed under reduced pressure, followed by purification of the reaction product with DI water, thereby obtaining 31 g of a semi-solid compound at a yield of 48%. NMR, LC-MS and elemental analysis confirmed that the corresponding compound was a compound represented by Formula 7 (A3).

¹H NMR (400 MHz, DMSO-d6): 7.50-7.45 (m, 4H), 7.43-7.37 (m, 4H), 7.02-6.92 (m, 4H), 6.88-6.76 (m, 4H), 4.20 (m, 2H), 3.95 (m, 2H), 3.94-3.90 (m, 4H), 3.58-3.40 (m, 8H) 3.23 (m, 2H), 2.75 (m, 2H), 2.41 (m, 2H), 1.89 (m, 4H), 1.65 (m, 2H) ppm; LC-MS m/z=640 (M⁺); Anal. Calcd for C₃₉H₄₄O₈: C, 73.10; H, 6.92; Found: C, 73.54; H, 6.62.

### Preparative Example 4: Preparation of Epoxy Resin

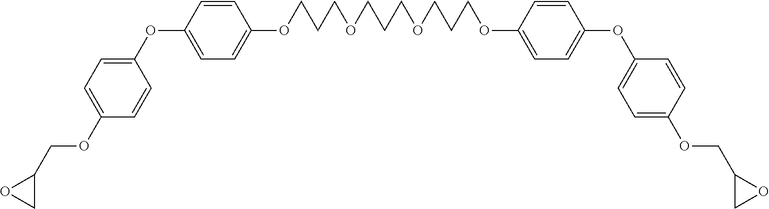 [SMILES: c1cc(Oc2ccc(OCC3CO3)cc2)ccc1OCCCOCCCOCCCOc1ccc(Oc2ccc(OCC3CO3)cc2)cc1]

In a 500 mL reactor placed in a microwave reactor (CEM Discovery, CEM Co., Ltd.), 100 mL of dimethylformamide (DMF) as a solvent, 4,4′-dihydroxybiphenyl ether (40.4 g), and triethylene glycol (19 g) were placed together with 20 mL of trimethylamine, followed by reaction at a temperature of 150° C. and a power of 150 W for 1 hour. Thereafter, the solvent was dried under reduced pressure, followed by purification of the reaction product through a silica gel column using a mixture of ethyl acetate and hexane (1:6) as a solvent. Thereafter, 31 g of a solid powder (yield: 54%) obtained through purification through the silica gel column was placed in a 500 mL reactor together with benzyltrimethylammonium bromide (5.0 g) and an excess of epichlorohydrin (300 mL), followed by reaction at 110° C. for 1 hour. Thereafter, NaOH (6 g) was added to the reactor, followed by reaction for 2 hours. Thereafter, the solvent was removed under reduced pressure, followed by purification of the reaction product with DI water, thereby obtaining 31 g of a semi-solid compound at a yield of 45%. NMR, LC-MS and elemental analysis confirmed that the corresponding compound was a compound represented by Formula 8 (A4).

¹H NMR (400 MHz, DMSO-d6): 6.94-6.68 (m, 16H), 4.20 (m, 2H), 3.95 (m, 2H), 3.94-3.90 (m, 4H), 3.58-3.40 (m, 8H) 3.23 (m, 2H), 2.75 (m, 2H), 2.41 (m, 2H), 1.89 (m, 4H), 1.68 (m, 2H) ppm; LC-MS m/z=672 (M⁺); Anal. Calcd for C₃₉H₄₄O₁₀: C, 69.63; H, 6.59; Found: C, 69.58; H, 6.37.

Details of components used in the Examples and Comparative Examples were as follows:
(A) Epoxy resin
(A1) An epoxy resin of Preparative Example 1
(A2) An epoxy resin of Preparative Example 2
(A3) An epoxy resin of Preparative Example 3
(A4) An epoxy resin of Preparative Example 4
(A5) An epoxy resin represented by the following formula:

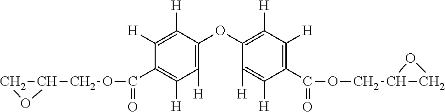 [SMILES: O=C(OCC1CO1)c1ccc(Oc2ccc(C(=O)OCC3CO3)cc2)cc1]

(A6) A biphenyl epoxy resin (NC-3000, Nippon Kayaku Co., Ltd.)
(B) Curing agent
(B1) KPH-F3065 (Xylok phenol resin, Kolon Chemical Co., Ltd.)
(B2) MEH-7851 (aralkyl-type phenol resin, Meiwa Corporation)
(C) Curing catalyst: Triphenyl phosphine (Hokko Chemical Co., Ltd.)
(D) Inorganic filler: A mixture of spherical fused alumina having an average particle diameter (D₅₀) of 20 μm and spherical fused alumina having an average particle diameter (D₅₀) of 0.5 μm (weight ratio: 9:1)
(E) Coupling agent
(E1) Methyltrimethoxysilane (SZ-6070, Dow Corning Corporation)
(E2) KBM-573 (N-phenyl-3-aminopropyltrimethoxysilane, Shinetsu Chemical Co., Ltd.)
(F) Carbon black (MA-600B, Mitsubishi Chemical Co., Ltd.)

### Examples 1 to 5 and Comparative Examples 1 to 4

The aforementioned components were uniformly mixed in amounts shown in Table 1 (unit: parts by weight) in a Henschel mixer (KSM-22, KEUM SUNG MACHINERY Co., Ltd.) at a temperature of 25° C. to 30° C. for 30 minutes. Thereafter, the mixture was subjected to melt-kneading in a continuous kneader at a temperature of up to 110° C. for 30 minutes, cooled to a temperature of 10° C. to 15° C., and pulverized, thereby preparing an epoxy resin composition for encapsulation of semiconductor devices. In Table 1, “-” means that a corresponding component was not used.

Each of the epoxy resin compositions prepared in the Examples and Comparative Examples was evaluated as to the following properties. Results are shown in Table 1.

(1) Fluidity (spiral flow length, unit: inch): Using a low-pressure transfer molding machine, each of the prepared epoxy resin compositions was injected into a mold for measurement of fluidity under conditions of a mold temperature of 175° C., a load of 70 kgf/cm², an injection pressure of 9 MPa, and a curing time of 90 seconds in accordance with EMMI-1-66, followed by measurement of flow length. A greater flow length indicates better fluidity.

(2) Toughness (unit: kgf/mm²): In accordance with ASTM D-790, a standard specimen (size: 125 mm×12.6 mm×6.4 mm (length×width×thickness)) was prepared from each of the prepared epoxy resin compositions and was cured at 175° C. for 4 hours, followed by measurement of toughness of the specimen at 25° C. using a Universal Testing Machine (UTM).

(3) Thermal conductivity (unit: W/m·K): Thermal conductivity was measured on a specimen prepared from each of the prepared epoxy resin compositions at 25° C. in accordance with ASTM D5470. Specifically, a specimen for measurement of thermal conductivity was prepared in accordance with ASTM D5470 by injecting each of the prepared epoxy resin compositions into a transfer molding machine under conditions of a mold temperature of 175° C., injection pressure of 9 MPa, and a curing time of 120 seconds. Thereafter, thermal conductivity of the specimen was measured at 25° C. using a flash laser thermal conductivity meter (LFA467, NETZSCH Instruments Inc.).

(4) Reliability (Unit: number): A semiconductor package manufactured using each of the prepared epoxy resin compositions was dried at 125° C. for 24 hours and then subjected to a thermal shock test of 5 cycles (1 cycle being defined as leaving the package at −65° C. for 10 minutes, at 25° C. for 10 minutes, and at 150° C. for 10 minutes). Thereafter, the presence of external cracks was observed under an optical microscope after pre-conditioning treatment in which a process of leaving the package at 85° C. and 60% RH for 168 hours, followed by IR reflow at 260° C. for 30 seconds was repeated three times. Thereafter, the presence of delamination between the epoxy resin composition and a lead frame was evaluated by scanning acoustic microscopy (C-SAM), which is a non-destructive testing method. Generation of external cracks in a semiconductor package or occurrence of delamination between the epoxy resin composition and the package indicates that the corresponding semiconductor package had poor reliability.

TABLE 1

| | | Example | | | | | Comparative Example | | | |
|---|---|---|---|---|---|---|---|---|---|---|
| | | 1 | 2 | 3 | 4 | 5 | 1 | 2 | 3 | 4 |
| (A) | (A1) | 5.2 | 5.2 | — | — | — | — | — | — | — |
| | (A2) | — | — | 5.2 | — | — | — | — | — | — |
| | (A3) | — | — | — | 5.2 | — | — | — | — | — |
| | (A4) | — | — | — | — | 5.2 | — | — | — | — |
| | (A5) | — | — | — | — | — | 5.2 | 5.2 | — | — |
| | (A6) | — | — | — | — | — | — | — | 5.2 | 5.2 |
| (B) | (B1) | 4.4 | — | 4.4 | 4.4 | 4.4 | 4.4 | — | 4.4 | — |
| | (B2) | — | 4.4 | — | — | — | — | 4.4 | — | 4.4 |
| (C) | | 0.5 | 0.5 | 0.5 | 0.5 | 0.5 | 0.5 | 0.5 | 0.5 | 0.5 |
| (D) | | 89 | 89 | 89 | 89 | 89 | 89 | 89 | 89 | 89 |
| (E) | (E1) | 0.2 | 0.2 | 0.2 | 0.2 | 0.2 | 0.2 | 0.2 | 0.2 | 0.2 |
| | (E2) | 0.2 | 0.2 | 0.2 | 0.2 | 0.2 | 0.2 | 0.2 | 0.2 | 0.2 |
| (F) | | 0.5 | 0.5 | 0.5 | 0.5 | 0.5 | 0.5 | 0.5 | 0.5 | 0.5 |
| Total | | 100 | 100 | 100 | 100 | 100 | 100 | 100 | 100 | 100 |
| Fluidity | | 65 | 63 | 67 | 69 | 70 | 59 | 57 | 55 | 58 |
| Toughness | | 0.72 | 0.78 | 0.71 | 0.80 | 0.75 | 0.49 | 0.52 | 0.45 | 0.50 |
| Thermal conductivity | | 6.1 | 6.3 | 6.5 | 6.0 | 6.4 | 5.1 | 5.3 | 4.6 | 4.7 |
| Reliability | External | 0 | 0 | 0 | 0 | 0 | 10 | 8 | 15 | 10 |
| | cracks | | | | | | | | | |
| | Delamination | 0 | 0 | 0 | 0 | 0 | 2 | 2 | 2 | 1 |
| | Number of | 88 | 88 | 88 | 88 | 88 | 88 | 88 | 88 | 88 |
| | tested | | | | | | | | | |
| | package | | | | | | | | | |
| | specimens | | | | | | | | | |

As can be seen from Table 1, the epoxy resin compositions for encapsulation of semiconductor devices of Examples 1 to 5 exhibited good heat dissipation capacity due to high thermal conductivity thereof while having good properties in terms of fluidity and crack resistance.

Conversely, the compositions of Comparative Examples 1 to 4, prepared using an epoxy resin having a different structure than the epoxy resin according to the embodiments, had lower thermal conductivity than the compositions of Examples 1 to 5 and exhibited poor reliability due to low crack resistance thereof.

By way of summation and review, a heatsink formed of a heat dissipation material, e.g., a metal may be bonded to a semiconductor package upon molding of an epoxy resin for encapsulation. However, such a heatsink may only be used in some packages, e.g., a fine pitch ball grid array (FBGA) and a quad flat package (QFP) and may be more expensive and require additional assembly processes. Therefore, there has been urgent demand for an epoxy resin molding material for encapsulation of semiconductor devices, which may have high thermal conductivity and good heat dissipation capacity. Some semiconductor packages may use spherical aluminum oxide (alumina).

To impart high thermal conductivity to resin compositions or epoxy molding compounds, a method of using aluminum oxide (alumina), which may have a higher thermal conductivity (25 W/m·K to 30 W/m·K) than silicon oxide may be used. However, some resins used in resin compositions for encapsulation of semiconductors may have very low thermal conductivities of about 0.2 W/m·K, which may make it difficult to obtain a resin composition having a thermal conductivity of 6 W/m·K or more.

Use of large amounts of inorganic filler in a resin composition for encapsulation of semiconductors may cause wire sweeping due to increase in viscosity of the composition and may cause void defects due to difficulty in forming a package caused by reduction in fluidity of the composition. Increase in a filling rate of inorganic filler to increase thermal conductivity of the resin composition may lead to damage to semiconductor chips or cracking of a package due to stress in the package if the package is subjected to external shock or reliability testing related to moisture absorption. In addition, since heat generated during operation of a semiconductor device may pass through a resin on a heat transfer path, high thermal conductivity of the filler may not be able to ensure effective heat transfer if the resin has low thermal conductivity.

It is an aspect of the present disclosure to provide an epoxy resin composition for encapsulation of semiconductor devices that may help provides significantly improved heat dissipation due to high thermal conductivity thereof while having good properties in terms of fluidity and crack resistance.

In accordance with one aspect of the present disclosure, there may be provided an epoxy resin composition for encapsulation of semiconductor devices.

Embodiments of the present invention may provide an epoxy resin composition for encapsulation of semiconductor devices that may help provide significantly improved heat dissipation due to high thermal conductivity thereof while having good properties in terms of fluidity and crack resistance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An epoxy resin composition for encapsulation of semiconductor devices, the epoxy resin composition comprising:
an epoxy resin;
a curing agent;
an inorganic filler; and
a curing catalyst,
wherein the epoxy resin includes at least one epoxy resin compound represented by Formula 1: 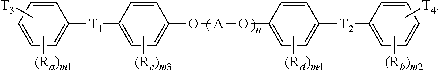
wherein A is a substituted or unsubstituted ethylene group or a substituted or unsubstituted propylene group,
n is an integer of 1 to 10,
T₁ and T₂ are each independently a single bond, O, or S,
T₃ and T₄ are each independently a compound represented by Formula 2: 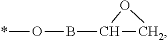
* is a linking site to a carbon of Formula 1,
B is a substituted or unsubstituted C₁ to C₅ alkylene group,
Rₐ, R_{b}, R_{c}, and R_{d} are each independently a substituted or unsubstituted C₁ to C₁₀ alkyl group, a substituted or unsubstituted C₃ to C₁₀ cycloalkyl group, a substituted or unsubstituted C₆ to C₁₀ aryl group, or a substituted or unsubstituted C₇ to C₁₀ arylalkyl group,
m1 and m2 are each independently an integer of 0 to 4, and
m3 and m4 are each independently an integer of 0 to 4.

2. The epoxy resin composition as claimed in claim 1, wherein the at least one epoxy resin compound represented by Formula 1 includes at least one compound represented by Formula 3 or Formula 4, 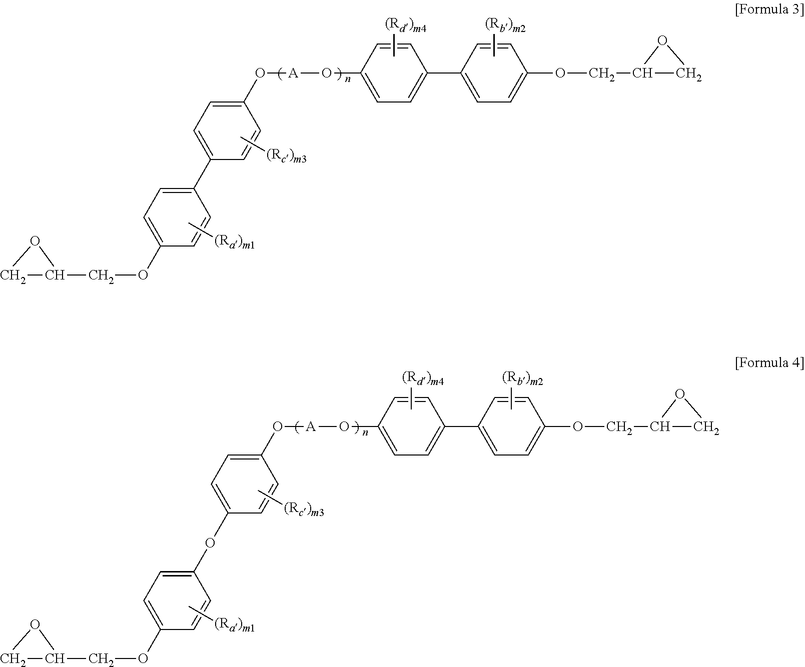
wherein Rₐ′, R_{b}′, R_{c}′, and R_{d}′ are each independently a substituted or unsubstituted C₁ to C₁₀ alkyl group, and
A, m1, m2, m3, m4, and n are defined the same as those of Formula 1.

3. The epoxy resin composition as claimed in claim 1, wherein the at least one epoxy resin compound represented by Formula 1 includes at least one compound represented by Formula 5 to Formula 8,

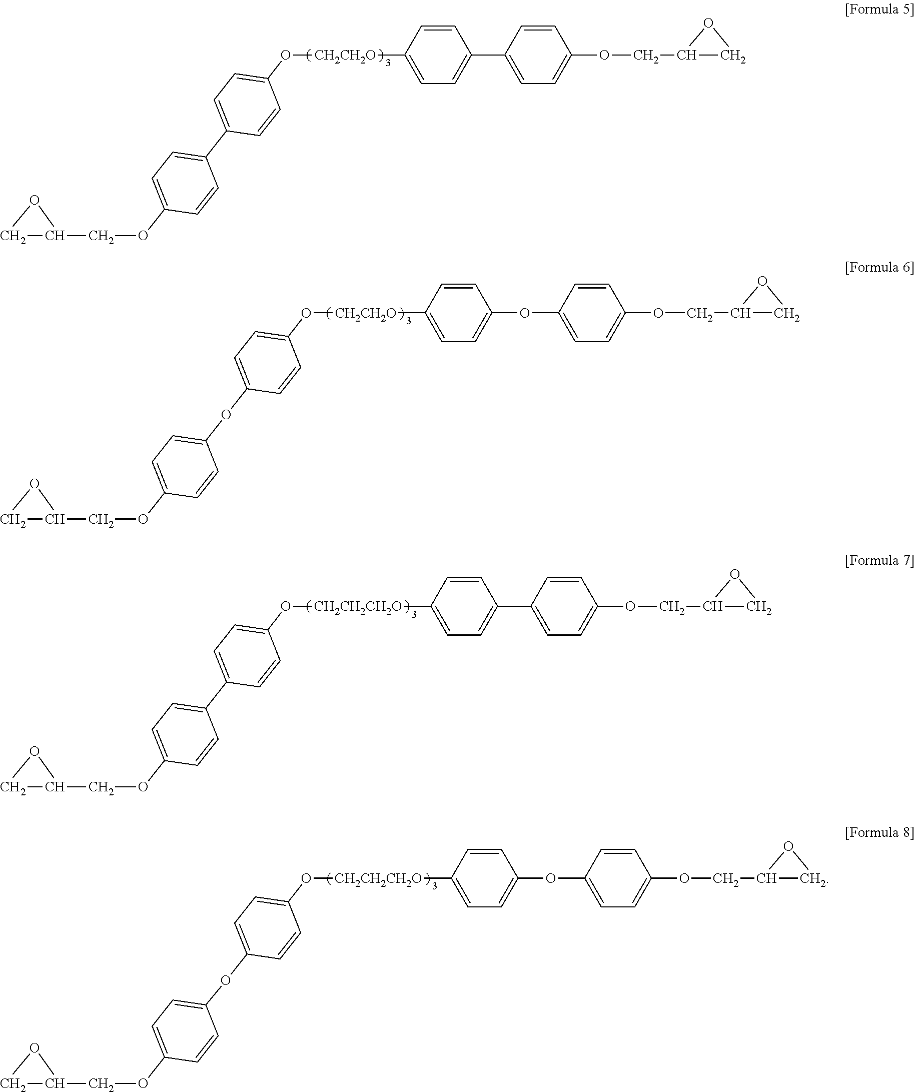

4. The epoxy resin composition as claimed in claim 1, wherein the at least one epoxy resin compound represented by Formula 1 is included in the epoxy resin composition in an amount of 0.1 wt % to 17 wt %, based on a total weight of the epoxy resin composition.

5. The epoxy resin composition as claimed in claim 1, wherein the inorganic filler includes alumina.

6. The epoxy resin composition as claimed in claim 1, wherein the epoxy resin composition includes, based on a total weight of the epoxy resin composition,
2 wt % to 17 wt % of the epoxy resin;
0.5 wt % to 13 wt % of the curing agent;
50 wt % to 95 wt % of the inorganic filler; and
0.01 wt % to 5 wt % of the curing catalyst.

7. A semiconductor device, the semiconductor device encapsulated using the epoxy resin composition as claimed in claim 1.

8. The semiconductor device as claimed in claim 7, wherein the at least one epoxy resin compound represented by Formula 1 includes at least one compound represented by Formula 3 or Formula 4, 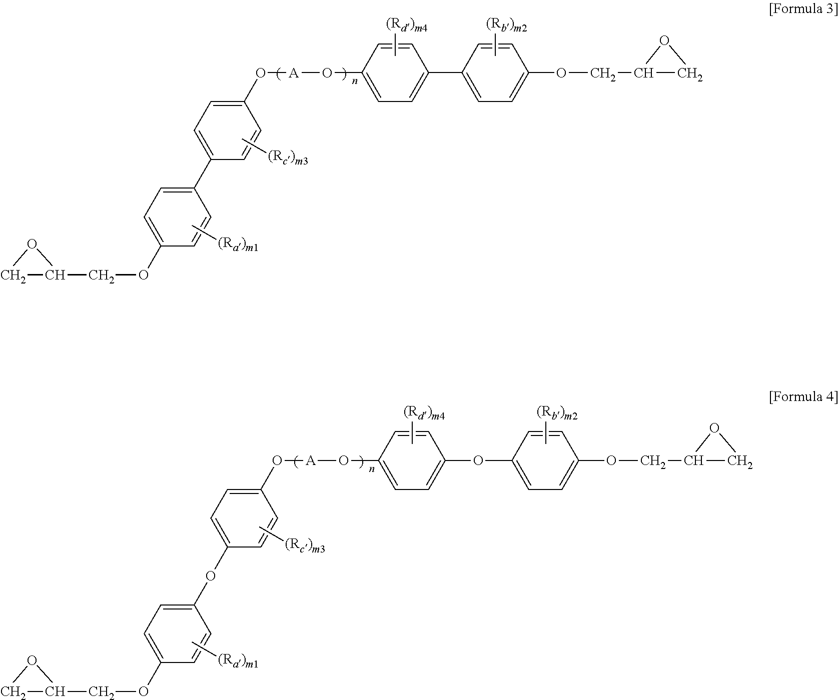
wherein Rₐ′, R_{b}′, R_{c}′, and R_{d}′ are each independently a substituted or unsubstituted C₁ to C₁₀ alkyl group, and
A, m1, m2, m3, m4, and n are defined the same as those of Formula 1.

9. The semiconductor device as claimed in claim 7, wherein the at least one epoxy resin compound represented by Formula 1 includes least one compound represented by Formula 5 to Formula 8,

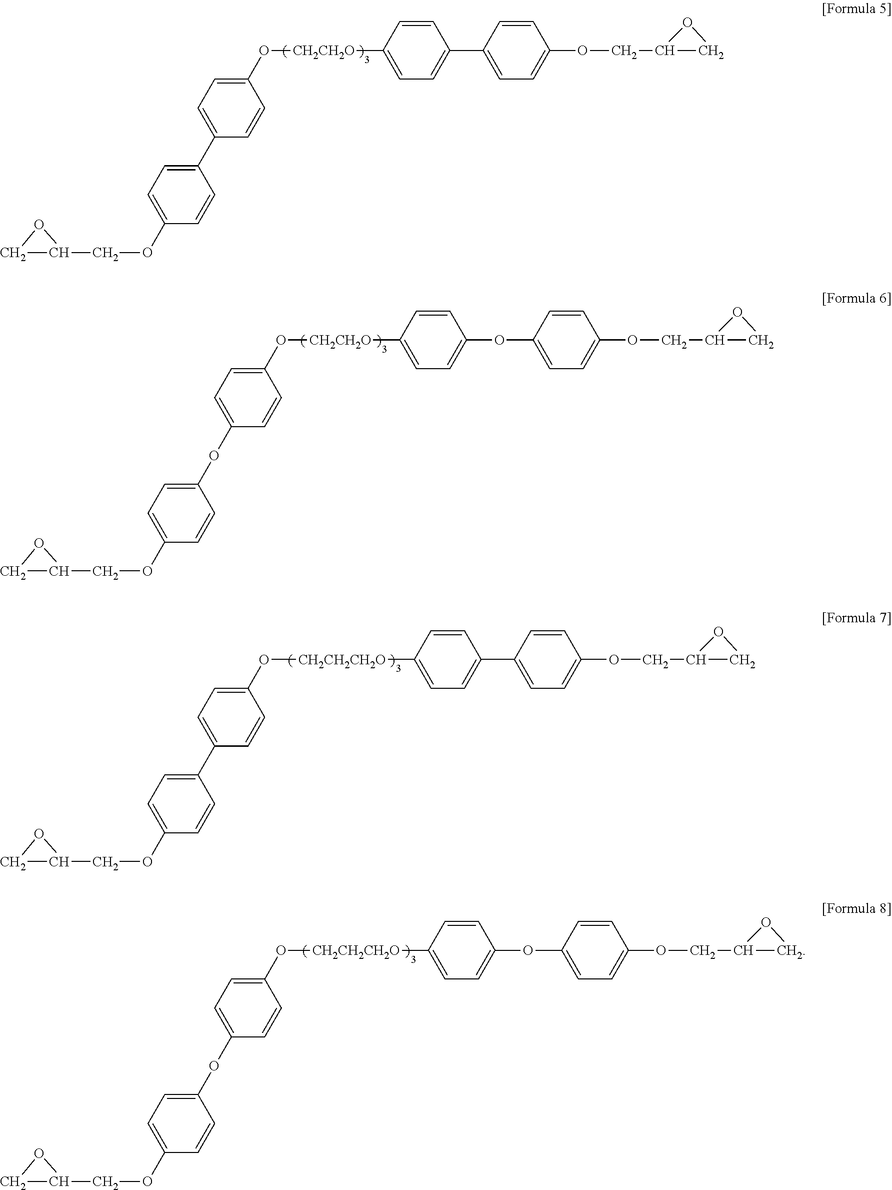

10. The semiconductor device as claimed in claim 7, wherein the at least one epoxy resin compound represented by Formula 1 is included in the epoxy resin composition in an amount of 0.1 wt % to 17 wt %, based on a total weight of the epoxy resin composition.

11. The semiconductor device as claimed in claim 7, wherein the inorganic filler includes alumina.

12. The semiconductor device as claimed in claim 7, wherein the epoxy resin composition includes, based on a total weight of the epoxy resin composition,
2 wt % to 17 wt % of the epoxy resin;
0.5 wt % to 13 wt % of the curing agent;
50 wt % to 95 wt % of the inorganic filler; and
0.01 wt % to 5 wt % of the curing catalyst.
